(19) United States
(12) Patent Application Publication
(10) Pub. No.: US 2023/0200240 A1
(43) Pub. Date: Jun. 22, 2023

(54) THERMOELECTRIC CONVERSION MODULE AND MANUFACTURING METHOD THEREFOR

(71) Applicant: LINTEC CORPORATION, Itabashi-ku (JP)

(72) Inventors: Yuta SEKI, Kawasaki-shi (JP); Wataru MORITA, Saitama-shi (JP); Kunihisa KATO, Warabi-shi (JP)

(73) Assignee: LINTEC CORPORATION, Itabashi-ku (JP)

(21) Appl. No.: 18/000,109

(22) PCT Filed: May 26, 2021
(86) PCT No.: PCT/JP2021/019991

§ 371 Date: Nov. 28, 2022

(30) Foreign Application Priority Data
May 29, 2020 (JP) 2020-094673

(51) Int. Cl. H10N 10/817; H10N 10/01; H10N 10/17

(52) U.S. Cl. CPC H10N 10/817; H10N 10/01; H10N 10/17

(57) ABSTRACT

A thermoelectric conversion module including, a first substrate having a first electrode, a second substrate having a second electrode, a chip of a thermoelectric conversion material made from a thermoelectric semiconductor composition, a first bonding material layer made from a first bonding material and bonding one surface of the chip of the thermoelectric conversion material and the first electrode, and a second bonding material layer made from a second bonding material and bonding another surface of the chip of the thermoelectric conversion material and the second electrode. A melting point of the second bonding material is lower than a melting point of the first bonding material, or the melting point of the second bonding material is lower than a curing temperature of the first bonding material.

### TECHNICAL FIELD

The present invention relates to a thermoelectric conversion module and a method for manufacturing the same.

### BACKGROUND ART

Typically, one means for effectively utilizing energy is a device that directly inter-converts thermal energy and electrical energy using a thermoelectric conversion module having a thermoelectric effect such as a Seebeck effect or a Peltier effect.

As such a thermoelectric conversion module, a configuration of a so-called π-type thermoelectric conversion element is known. The π-type thermoelectric conversion element is configured by providing, on a substrate, a pair of electrodes that are mutually spaced apart, for example, providing a P-type thermoelectric element on one electrode and an N-type thermoelectric element on the other electrode with the electrodes being similarly spaced apart from each other, and connecting the upper surfaces of both of the thermoelectric elements to the electrodes of an opposing substrate.

In the mounting and assembly of a thermoelectric element of a thermoelectric conversion module having such a configuration, when one surface of the thermoelectric element is to be bonded to an opposing electrode and the other surface of the thermoelectric element is to be bonded to an opposing electrode, if, for example, the same solder material or solder materials having close melting points are used as the bonding material, when the other surface and an electrode are to be bonded after the one surface and an electrode have been bonded, the solder material used in the bonding of the one electrode also melts at the same time, and as a result, a positional deviation may occur in the thickness direction or in-plane direction of the thermoelectric element. As a result of the positional deviation, short circuiting may occur between a side surface of a P-type thermoelectric element and an adjacent side surface of an N-type thermoelectric element, or a decrease in thermoelectric performance may occur due to a defect in the bonding with the electrodes, and thus there is a demand to suppress these issues.

A thermoelectric conversion module disclosed in Patent Document 1 relates to preventing cracking due to a difference in thermal expansion of thermoelectric conversion elements. Patent Document 1 describes bonding between a thermoelectric conversion element and an electrode part in a first bonding step and bonding between a thermoelectric conversion element and an electrode part in a second bonding step, and indicates that in the second bonding step, bonding is implemented at a bonding temperature that is lower than the bonding temperature in the first bonding step.

### CITATION LIST

### Patent Literature

Patent Document 1: JP 2018-67589 A

### SUMMARY OF INVENTION

### Technical Problem

However, in addition to pertaining to the prevention of cracking due to a difference in thermal expansion of the thermoelectric conversion elements, the thermoelectric conversion module of Patent Document 1 is such that bonding between the thermoelectric conversion element (thermoelectric conversion material: silicide-based, oxide-based) and the electrode part in the first bonding step is implemented by brazing [silver (Ag) solder], and bonding between the thermoelectric conversion element and the electrode part in the second bonding step is implemented by soldering or using a silver paste. Moreover, brazing to bond the thermoelectric conversion element and the electrode part in the first bonding step is implemented, for example, by heating at a bonding temperature of 605° C. to 780° C. for a bonding time from 1 minute to 10 minutes.

Thus, for example, when the thermoelectric conversion material is formed from a thermoelectric semiconductor composition containing a resin, the composition, shape, and the like of the formed thermoelectric element layer change at the bonding temperature of the first bonding step, and the thermoelectric performance may be significantly reduced.

The present invention was conceived in light of such circumstances, and an object of the present invention is to provide a thermoelectric conversion module that prevents positional deviation of a chip of a thermoelectric conversion material on an electrode, the positional deviation resulting from the bonding material, and suppresses short circuiting between adjacent chips of thermoelectric conversion materials and bonding defects between a chip of a thermoelectric conversion material and an electrode, and to provide a method for manufacturing the same.

### Solution to Problem

As a result of diligent research to solve the problems described above, the present inventors discovered that, in the bonding between an electrode and a chip of a thermoelectric conversion material constituting a thermoelectric conversion module, when a first bonding material and a second bonding material are used with the melting point of the second bonding material being lower than the melting point of the first bonding material, or the melting point of the second bonding material being lower than a curing temperature of the first bonding material, positional deviation of the chip of the thermoelectric conversion material on the electrode that occurs due to the first bonding material when bonding the second bonding material is prevented, and short circuiting between adjacent chips of thermoelectric conversion materials and bonding defects between an electrode and a chip of a thermoelectric conversion material are suppressed, and thereby the present inventors arrived at the present invention.

That is, the present invention provides the following aspects (1) to (12).

(1) A thermoelectric conversion module including: a first substrate having a first electrode; a second substrate having a second electrode; a chip of a thermoelectric conversion material made from a thermoelectric semiconductor composition; a first bonding material layer made from a first bonding material and bonding one surface of the chip of the thermoelectric conversion material and the first electrode; and a second bonding material layer made from a second bonding material and bonding another surface of the chip of the thermoelectric conversion material and the second electrode, wherein
a melting point of the second bonding material is lower than a melting point of the first bonding material, or the melting point of the second bonding material is lower than a curing temperature of the first bonding material.

(2) The thermoelectric conversion module according to (1), wherein a difference between the melting point of the first bonding material and the melting point of the second bonding material is 20° C. or higher

(3) The thermoelectric conversion module according to (1), wherein a difference between the curing temperature of the first bonding material and the melting point of the second bonding material is 20° C. or higher.

(4) The thermoelectric conversion module according to (1) or (2), wherein the first bonding material and the second bonding material are solder materials.

(5) The thermoelectric conversion module according to (1) or (3), wherein the first bonding material is a conductive adhesive material, and the second bonding material is a solder material.

(6) The thermoelectric conversion module according to (1), wherein the thermoelectric semiconductor composition includes a resin.

(7) The thermoelectric conversion module according to (6), wherein the resin is a heat-resistant resin, and furthermore, the thermoelectric semiconductor composition contains a thermoelectric semiconductor material and one or both of an ionic liquid and an inorganic ionic compound.

(8) The thermoelectric conversion module according to (7), wherein the heat-resistant resin is a polyimide resin, a polyamide resin, a polyamide-imide resin, or an epoxy resin.

(9) The thermoelectric conversion module according to (6), wherein the resin is a binder resin, and furthermore, the thermoelectric semiconductor composition contains a thermoelectric semiconductor material and one or both of an ionic liquid and an inorganic ionic compound.

(10) The thermoelectric conversion module according to (9), wherein the binder resin includes at least one selected from polycarbonates, cellulose derivatives, and polyvinyl polymers.

(11) A method for manufacturing a thermoelectric conversion module including: a first substrate having a first electrode; a second substrate having a second electrode; a chip of a thermoelectric conversion material made from a thermoelectric semiconductor composition; a first bonding material layer made from a first bonding material and bonding one surface of the chip of the thermoelectric conversion material and the first electrode; and a second bonding material layer made from a second bonding material and bonding another surface of the chip of the thermoelectric conversion material and the second electrode, the manufacturing method including:
(a) a step of forming, on the first electrode on the first substrate, the first bonding material layer made from the first bonding material; (b) a step of mounting one surface of the chip of the thermoelectric conversion material on the first bonding material layer obtained in step (a); (c) a first bonding step of bonding, to the first electrode, one surface of the chip of the thermoelectric conversion material mounted in step (b), by interposing and heating the first bonding material layer obtained in step (a); (d) a step of forming, on the second electrode on the second substrate, the second bonding material layer made from the second bonding material; (e) a step of pasting together the other surface of the chip of the thermoelectric conversion material on the first substrate and the second bonding material layer obtained in step (d); and (f) a second bonding step of bonding the other surface of the chip of the thermoelectric conversion material after the step (e) to the second electrode by interposing and heating the second bonding material layer; wherein
a bonding temperature of the second bonding step is lower than a bonding temperature of the first bonding step.

(12) The method for manufacturing a thermoelectric conversion module according to (11), wherein heating in the first bonding step and the second bonding step is implemented by reflow.

### Advantageous Effects of Invention

According to the present invention, a thermoelectric conversion module that prevents positional deviation of a chip of a thermoelectric conversion material on an electrode, the positional deviation resulting from the bonding material, and suppresses short circuiting between adjacent chips of thermoelectric conversion materials and bonding defects between a chip of a thermoelectric conversion material and an electrode, and a method for manufacturing the same can be provided.

### BRIEF DESCRIPTION OF DRAWINGS

FIG. 1 is a cross-sectional view for explaining an example of a configuration of a thermoelectric conversion module that includes a bonding material layer and is used in the present invention.

FIG. 2 is an explanatory diagram illustrating, in order of steps, an example of a method for bonding a chip of a thermoelectric conversion material and an electrode by the method for manufacturing a thermoelectric conversion module of the present invention.

### DESCRIPTION OF EMBODIMENTS

### [Thermoelectric Conversion Module]

A thermoelectric conversion module according to the present inventions includes: a first substrate having a first electrode; a second substrate having a second electrode; a chip of a thermoelectric conversion material made from a thermoelectric semiconductor composition; a first bonding material layer made from a first bonding material and bonding one surface of the chip of the thermoelectric conversion material and the first electrode; and a second bonding material layer made from a second bonding material and bonding another surface of the chip of the thermoelectric conversion material and the second electrode; and is characterized in that a melting point of the second bonding material is lower than a melting point of the first bonding material, or the melting point of the second bonding material is lower than a curing temperature of the first bonding material.

With the thermoelectric conversion module of the present invention, the melting point of the second bonding material is lower than the melting point of the first bonding material, or the melting point of the second bonding material is lower than the curing temperature of the first bonding material, and therefore positional deviation of a chip of a thermoelectric conversion material on an electrode is prevented, and short circuiting between adjacent chips of thermoelectric conversion materials and bonding defects between an electrode and a chip of a thermoelectric conversion material are suppressed.

Note that in the present specification, “melting point” refers to a solidus temperature when, for example, a “solder material” to be described below is used as a bonding material. Furthermore, the “curing temperature” applies, for example, to a case in which a curable resin is included as a bonding material in a below-described “conductive adhesive material”.

Moreover, in the present specification, “one surface of a chip of a thermoelectric conversion material” and “another surface of the chip of the thermoelectric conversion material” refer to opposing upper and lower surfaces when, for example, the shape of the chip of the thermoelectric conversion material is rectangular parallelepiped or cylindrical, and the chip is viewed from the front.

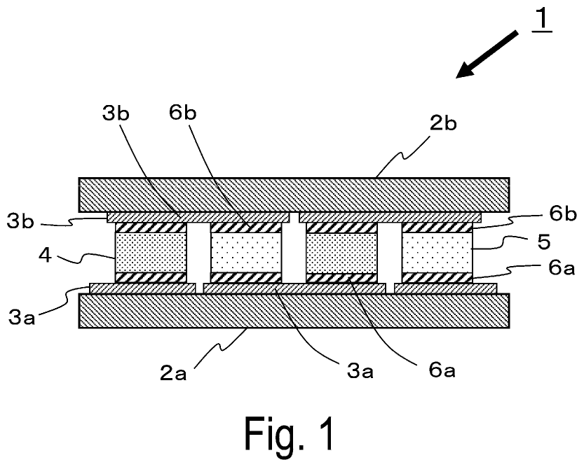

FIG. 1 is a cross-sectional view for explaining an example of a configuration of a thermoelectric conversion module of the present invention. A thermoelectric conversion module 1 is configured from a so-called π-type thermoelectric conversion element, has a first substrate 2a and a second substrate 2b, which are mutually opposing, includes a first bonding material layer 6a made from a first bonding material and formed between a first electrode 3a formed on the first substrate 2a and one surface of each of a chip 4 of a P-type thermoelectric conversion material and a chip 5 of an N-type thermoelectric conversion material, and further includes a second bonding material layer 6b made from a second bonding material and formed between a second electrode 3b formed on the second substrate 2b and the other surface of each of the chip 4 of the P-type thermoelectric conversion material and the chip 5 of the N-type thermoelectric conversion material.

### <Bonding Material Layer>

The first bonding material layer made from the first bonding material and the second bonding material layer made from the second bonding material are used in the thermoelectric conversion module of the present invention.

The first bonding material layer electrically and physically bonds one surface of the chip of the thermoelectric conversion material with the first electrode, and similarly, the second bonding material layer electrically and physically bonds the other surface of the chip of the thermoelectric conversion material with the second electrode.

The melting point of the second bonding material used in the present invention is lower than the melting point of the first bonding material. If the melting point of the second bonding material is higher than the melting point of the first bonding material, when the other surface of the chip of the thermoelectric conversion material and the second electrode are bonded, a bonding portion (first bonding material layer) between the one surface of the chip of the thermoelectric conversion material and the first electrode, which were bonded in advance, melts, and a positional deviation of at least the chip of the thermoelectric conversion material on the first electrode easily occurs. The difference between the melting point of the first bonding material and the melting point of the second bonding material is preferably at least 20° C., more preferably at least 30° C., and even more preferably at least 50° C. When the difference between the melting point of the first bonding material and the melting point of the second bonding material is within this range, even though the second bonding material is heated, that is, even though bonding of the other surface of the chip of the thermoelectric conversion material to the second electrode is implemented, the bonding portion (first bonding material layer) between the one surface of the chip of the thermoelectric conversion material and the first electrode, which were bonded in advance, is maintained, positional deviation of the chip of the thermoelectric conversion material on the first electrode is prevented, and short circuiting between adjacent chips of the thermoelectric conversion material and bonding defects between the chip of the thermoelectric conversion material and the first electrode are suppressed. Note that the upper limit value of the temperature difference is not particularly limited, but, for example, the composition, shape, and the like of the formed thermoelectric element layer may change, and the thermoelectric performance may be significantly reduced, and therefore an upper limit of 100° C. or lower is preferable.

The range of the melting point of the first bonding material is preferably from 220° C. to 350° C., more preferably from 220° C. to 300° C., and particularly preferably from 220° C. to 250° C. When the melting point of the first bonding material is within this range, the substrate and the chip of the thermoelectric conversion material is less likely to be damaged.

Similarly, when a curable resin is used for the first bonding material, the melting point of the second bonding material used in the present invention is lower than the curing temperature of the first bonding material. If the melting point of the second bonding material is higher than the curing temperature of the first bonding material, when the other surface of the chip of the thermoelectric conversion material and the second electrode are bonded, cracking and deformation, etc. occur in the bonding portion (first bonding material layer) between the one surface of the chip of the thermoelectric conversion material and the first electrode, which were bonded in advance, and peeling and positional deviation, etc. of at least the chip of the thermoelectric conversion material on the first electrode easily occur. The difference between the curing temperature of the first bonding material and the melting point of the second bonding material is preferably at least 20° C., more preferably at least 30° C., and even more preferably at least 50° C. When the difference between the curing temperature of the first bonding material and the melting point of the second bonding material is within this range, even though the second bonding material is heated, that is, even though bonding of the other surface of the chip of the thermoelectric conversion material to the second electrode is implemented, the bonding portion (first bonding material layer) between the one surface of the chip of the thermoelectric conversion material and the first electrode, which were bonded in advance, is maintained, positional deviation of the chip of the thermoelectric conversion material on the first electrode is prevented, and short circuiting between adjacent chips of the thermoelectric conversion material and bonding defects between the chip of the thermoelectric conversion material and the first electrode are suppressed. Note that the upper limit value of the temperature difference is not particularly limited, but, for example, the composition, shape, and the like of the formed thermoelectric element layer may change, and the thermoelectric performance may be significantly reduced, and therefore an upper limit of 100° C. or lower is preferable.

The range of the melting point of the second bonding material is preferably from 100° C. to 200° C., and more preferably from 120° C. to 180° C. Setting the melting point of the second bonding material to within this range enables stable mounting of a chip of a thermoelectric conversion material.

Examples of bonding materials constituting the bonding material layer used in the present invention include solder materials, conductive adhesive materials, and sinter bonding materials. In one aspect, the first bonding material and the second bonding material are preferably solder materials. As another aspect, the first bonding material is a conductive adhesive material, and the second bonding material is a solder material.

### First Embodiment

In a first embodiment of the present invention, solder materials are used as the first bonding material and the second bonding material.

When solder materials are used as the first bonding material and the second bonding material, the liquidus temperature of the solder material used as the second bonding material is lower than the melting point (solidus temperature) of the solder material used as the first bonding material.

The solder material is selected with consideration of first, the melting point, and also of the heat resistance temperatures of the resins included in the substrate and the chip of the thermoelectric conversion material, and also the electrical conductivity and thermal conductivity.

The solder material is not particularly limited, but from the perspective of lead free and/or cadmium free designs, examples of solder materials having a relatively low melting point include Sn—In-based In52Sn48 [melting temperature: solidus temperature (approximately 119° C.), liquidus temperature (approximately 119° C.)], Sn—Bi-based Bi58Sn42 [melting temperature: solidus temperature (approximately 139° C.), liquidus temperature (approximately 139° C.)], Sn—Zn—Bi-based Sn89Zn8Bi3 [melting temperature: solidus temperature (approximately 190° C.), liquidus temperature (approximately 196° C.)], and Sn—Zn-based Sn91Zn9 [melting temperature: solidus temperature (approximately 198° C.), liquidus temperature (approximately 198° C.)].

Furthermore, from the perspective of lead free and/or cadmium free designs, examples of solder materials having a relatively high melting point include Sn—Sb-based Sn95Sb5 [melting temperature: solidus temperature (approximately 238° C.), liquidus temperature (approximately 241° C.)], Sn—Cu based Sn99.3Cu0.7 [melting temperature: solidus temperature (approximately 227° C.), liquidus temperature (approximately 228° C.)], Sn—Cu—Ag-based Sn99Cu0.7Ag0.3 [melting temperature: solidus temperature (approximately 217° C.), liquidus temperature (approximately 226° C.)], Sn—Ag-based Sn97Ag3 [melting temperature: solidus temperature (approximately 221° C.), liquidus temperature (approximately 222° C.)], Sn—Ag—Cu-based Sn96.5Ag3Cu0.5 [melting temperature: solidus temperature (approximately 217° C.), liquidus temperature (approximately 219° C.)] and Sn95.5Ag4Cu0.5 [melting temperature: solidus temperature (approximately 217° C.), liquidus temperature (approximately 219° C.)], and Sn—Ag—Cu-based Sn95.8Ag3.5Cu0.7 [melting temperature: solidus temperature (approximately 217° C.), liquidus temperature (approximately 217° C.)].

The solder materials and the like are combined and used, as appropriate, as the first bonding material and the second bonding material on the basis of the stipulations of the present invention. Preferably, the second bonding material is Bi58Sn42 or In52Sn48, and the first bonding material is Sn96.5Ag3Cu0.5 or Sn95Sb5. More preferably, the second bonding material is Bi58Sn42 and the first bonding material is Sn96.5Ag3Cu0.5.

Examples of commercially available solder material products that can be used include the following. For example, a 42Sn/58Bi alloy [available from Tamura Corporation, product name: SAM10-401-27, melting temperature: solidus temperature (approximately 139° C.), liquidus temperature (approximately 139° C.)], a 41Sn/58Bi/1.0Ag alloy [available from Nihon Honda Inc., product name: PF141-LT7HO, melting temperature: solidus temperature (approximately 136° C.), liquidus temperature (approximately 138° C.)], and a 96.5Sn3.0Ag0.5Cu alloy [available from Nihon Honda Inc., product name: PF305-153TO, melting temperature: solidus temperature (approximately 217° C.), liquidus temperature (approximately 219° C.)] can be used.

The thickness (after heating and cooling) of the solder material layer containing the solder material is preferably from 10 to 200 μm, more preferably from 20 to 150 μm, even more preferably from 30 to 130 μm, and particularly preferably from 40 to 120 μm. When the thickness of the solder material layer is within this range, adhesion of the chip of the thermoelectric conversion material to the electrode is facilitated.

Examples of methods of coating the solder material onto an electrode include known methods such as stencil printing, screen printing, and dispensing methods. The heating temperature varies depending on the solder material that is used, the substrate, and the like, but typically heating is implemented at a temperature from 100 to 350° C. for 0.5 to 20 minutes. When a solder material having a relatively high melting temperature is used, heating is preferably carried out at 200 to 280° C. for 0.5 to 10 minutes, and more preferably at 230 to 280° C. for 0.5 to 8 minutes. In addition, when a solder material having a relatively low melting point is used, heating is preferably carried out at 110 to 210° C. for 0.5 to 20 minutes, and more preferably at 110 to 195° C. for 1 to 20 minutes.

In the present embodiment, Sn—Ag—Cu-based Sn96.5Ag3Cu0.5 [melting temperature: solidus temperature (approximately 217° C.), liquidus temperature (approximately 219° C.)] is used as the solder material of the first bonding material, and Sn—Bi-based Bi58Sn42 [melting temperature: solidus temperature (approximately 139° C.), liquidus temperature (approximately 139° C.)] is used as the solder material of the second bonding material.

### Second Embodiment

In a second embodiment of the present invention, a conductive adhesive material is used as the first bonding material, and a solder material is used as the second bonding material.

The conductive adhesive material is not particularly limited, and examples thereof include conductive pastes containing metal particles of a conductive material such as silver, copper, or nickel. Examples of the conductive paste include a silver paste, a copper paste, and a nickel paste, and examples of a binder include epoxy-based thermosetting resins, acrylic-based thermosetting resins, and silicone-based thermosetting resins.

Among the conductive pastes, a silver paste is preferred from the perspective of electrical conductivity and versatility.

Examples of methods for coating the conductive adhesive material onto an electrode include known methods such as screen printing and a dispensing method. The heating temperature varies depending on the conductive adhesive material that is used, the substrate, and the like, but typically heating is implemented at 100 to 280° C. for 0.5 to 20 minutes, and preferably at 100 to 220° C. for 10 to 20 minutes.

The thickness of the conductive adhesive material layer containing the conductive adhesive material is preferably from 10 to 200 μm, more preferably from 20 to 150 μm, even more preferably from 30 to 130 μm, and particularly preferably from 40 to 120 μm.

Examples of commercially available conductive adhesive materials that can be used include the following. For example, the conductive adhesive material ECA300 (available from Nihon Honda Inc., conductive material: silver particles, resin: epoxy resin, curing temperature: 200° C.), the conductive adhesive material EPS-110A (available from Muromachi Chemicals Inc., conductive material: silver particles, resin: epoxy resin, curing temperature: 180° C.), and the conductive adhesive material K-72-1 LV (available from Muromachi Chemicals Inc., conductive material: silver particles, resin: epoxy resin, curing temperature: 150° C.) can be used.

In the present embodiment, the conductive adhesive material ECA300 (available from Nihon Honda Inc., conductive material: silver particles, resin: epoxy resin, curing temperature: 200° C.) is used as the conductive adhesive material of the first bonding material, and Sn—Bi-based Bi58Sn42 [melting temperature: solidus temperature (approximately 139° C.), liquidus temperature (approximately 139° C.)] was used as the solder material of the second bonding material.

The abovementioned sinter bonding material may be used as the first bonding material. The sinter bonding material is not particularly limited, and examples include sintering pastes. The sintering paste is formed from, for example, micron-sized metal particles and nano-sized metal particles, and unlike the conductive adhesive material, the sintering paste directly bonds metal through sintering, and may include a binder such as an epoxy resin, an acrylic resin, or a urethane resin.

Examples of the sintering paste include silver sintering pastes and copper sintering pastes.

Examples of methods for coating a sinter bonding material onto an electrode include known methods such as screen printing, stencil printing, and dispensing methods. The sintering conditions differ depending on factors such as the metal materials that are used, but usually include sintering at 100 to 300° C. for 30 to 120 minutes.

Examples of commercially available sinter bonding materials that can be used include silver sintering pastes such as CT2700R7S sintering paste (available from Kyocera Corporation), and the sintering-type metal bonding material MAX102 (available from Nihon Honda Inc.).

The thickness of the sinter bonding material layer containing the sinter bonding material is preferably from 10 to 200 μm, more preferably from 20 to 150 μm, even more preferably from 30 to 130 μm, and particularly preferably from 40 to 120 μm.

### <Chip of a Thermoelectric Conversion Material>

The chip of the thermoelectric conversion material used in the thermoelectric conversion module of the present invention is formed from a thin film of at least a thermoelectric semiconductor composition. The chip thereof is preferably formed from a thermoelectric semiconductor composition containing a thermoelectric semiconductor material (hereinafter, also referred to as “thermoelectric semiconductor particles”), a resin described below, and one or both of an ionic liquid and an inorganic ionic compound, which are described below.

### (Thermoelectric Semiconductor Material)

The thermoelectric semiconductor material used in the present invention, that is, the thermoelectric semiconductor material constituting the chip of the P-type thermoelectric conversion material and the chip of the N-type thermoelectric conversion material, is not particularly limited as long as the material is capable of generating a thermo-electromotive force by imparting a temperature difference. Examples of such thermoelectric semiconductor materials that can be used include bismuth-tellurium-based thermoelectric semiconductor materials such as a P-type bismuth telluride, and an N-type bismuth telluride; telluride-based thermoelectric semiconductor materials such as GeTe and PbTe; antimony-tellurium-based thermoelectric semiconductor materials; zinc-antimony-based thermoelectric semiconductor materials such as ZnSb, Zn₃Sb₂, and Zn₄Sb₃; silicon-germanium-based thermoelectric semiconductor materials such as SiGe; bismuth selenide-based thermoelectric semiconductor materials such as Bi₂Se₃; silicide-based thermoelectric semiconductor materials such as β-FeSi₂, CrSi₂, MnSi_{1.73}, and Mg₂Si; oxide-based thermoelectric semiconductor materials; Heusler materials such as FeVAl, FeVAlSi, and FeVTiAl; and sulfide-based thermoelectric semiconductor materials such as TiS₂.

Among these, a bismuth-tellurium-based thermoelectric semiconductor material, a telluride-based thermoelectric semiconductor material, an antimony-tellurium-based thermoelectric semiconductor material, or a bismuth selenide-based thermoelectric semiconductor material is preferable.

Furthermore, the thermoelectric semiconductor material is more preferably a bismuth-tellurium-based thermoelectric semiconductor material such as a P-type bismuth telluride or an N-type bismuth telluride.

The P-type bismuth telluride is preferably one for which the carrier is a positive hole and the Seebeck coefficient is a positive value, and for example, a P-type bismuth telluride represented by BixTe₃Sb_{2-X} is preferably used. In this case, X preferably satisfies 0<X≤0.8, and more preferably satisfies 0.4≤X≤0.6. When X is greater than 0 and less than or equal to 0.8, the Seebeck coefficient and electrical conductivity increase, and the characteristics as a P-type thermoelectric element are maintained, and thus X is preferably within this range.

In addition, the N-type bismuth telluride is preferably one for which the carrier is an electron and the Seebeck coefficient is a negative value, and, for example, an N-type bismuth telluride represented by Bi₂Te_{3-Y}Se_{Y} is preferably used. In this case, Y preferably satisfies 0≤Y≤3 (when Y=0:Bi₂Te₃), and more preferably satisfies 0<Y≤2.7. When Y is from 0 to 3, the Seebeck coefficient and electrical conductivity increase, and the characteristics as an N-type thermoelectric element are maintained, and thus Y is preferably within this range.

The compounded amount of the thermoelectric semiconductor material or thermoelectric semiconductor particles in the thermoelectric semiconductor composition is preferably from 30 to 99 mass %. The compounded amount thereof is more preferably from 50 to 96 mass %, and even more preferably from 70 to 95 mass %. If the compounded amount of the thermoelectric semiconductor particles is within the range described above, the Seebeck coefficient (absolute value of the Peltier coefficient) is large, a decrease in electrical conductivity is suppressed, and only thermal conductivity is reduced, and therefore a film exhibiting high thermoelectric performance and having sufficient film strength and flexibility is obtained. Thus, the compounded amount of the thermoelectric semiconductor particles is preferably within the range described above.

The average particle size of the thermoelectric semiconductor particles is preferably from 10 nm to 200 μm, more preferably from 10 nm to 30 μm, even more preferably from 50 nm to 10 μm, and particularly preferably from 1 to 6 μm. In a case where the average particle size is within the aforementioned range, uniform dispersion is facilitated, and electrical conductivity can be increased.

The thermoelectric semiconductor particles used in the chip of the thermoelectric conversion material are preferably particles obtained by grinding the above-described thermoelectric semiconductor material to a predetermined size using a pulverizer or the like.

The method for obtaining the thermoelectric semiconductor particles by grinding the thermoelectric semiconductor material is not particularly limited, and the material may be ground to a predetermined size using a known pulverizer such as a jet mill, a ball mill, a bead mill, a colloid mill, or a roller mill.

Note that the average particle size of the thermoelectric semiconductor particles is obtained by measuring using a laser diffraction particle size analyzer (Mastersizer 3000 available from Malvern Panalytical Ltd.), and using the median from the particle size distribution.

Furthermore, the thermoelectric semiconductor particles are preferably subjected to an annealing treatment (hereinafter, also referred to as an “annealing treatment A”). When the thermoelectric semiconductor particles are subjected to the annealing treatment A, the crystallinity of the thermoelectric semiconductor particles is improved, and a surface oxide film of the thermoelectric semiconductor particles is removed, and therefore the Seebeck coefficient or the Peltier coefficient of the thermoelectric conversion material increases, and the thermoelectric performance index can be further improved. The annealing treatment A is not particularly limited, but is preferably implemented prior to preparation of the thermoelectric semiconductor composition and is implemented in an atmosphere of inert gas such as nitrogen or argon with the gas flow rate controlled, or similarly, in an atmosphere of a reducing gas such as hydrogen, or in vacuum conditions, so as to not adversely affect the thermoelectric semiconductor particles, and is more preferably implemented in a mixed gas atmosphere of an inert gas and a reducing gas. The specific temperature conditions depend on the thermoelectric semiconductor particles that are used, but typically the annealing treatment A is preferably implemented for several minutes to several tens of hours at a temperature that is equal to or lower than the melting point of the particles and is from 100 to 1500° C.

(Resin)

The resin used in the present invention has a function of physically bonding the thermoelectric semiconductor material (thermoelectric semiconductor particles) together, and can increase the flexibility of the thermoelectric conversion module and facilitate the formation of a thin film through coating or the like.

The resin is preferably a heat-resistant resin or a binder resin.

When crystal growth of the thermoelectric semiconductor particles is caused by subjecting the thin film formed from the thermoelectric semiconductor composition to an annealing treatment or the like, the physical properties such as mechanical strength and thermal conductivity of the heat-resistant resin as a resin are maintained without being impaired.

From the perspective of further increasing heat resistance and not adversely affecting crystal growth of the thermoelectric semiconductor particles in the thin film, the heat-resistant resin is preferably a polyamide resin, a polyamide-imide resin, a polyimide resin, or an epoxy resin, and from the perspective of excelling in flexibility, the heat-resistant resin is more preferably a polyamide resin, a polyamide-imide resin, or a polyimide resin.

When a polyimide film is used as the first substrate or the second substrate described below, the heat-resistant resin is more preferably a polyimide resin or a polyamide-imide resin from perspectives such as adherence with the polyimide film. Note that in the present invention, the term polyimide resin is used as a general term for polyimides and precursors thereof.

The heat-resistant resin preferably has a decomposition temperature of 300° C. or higher. If the decomposition temperature is within the range described above, flexibility can be maintained without loss of function as a binder even when the thin film formed from the thermoelectric semiconductor composition is annealed as described below.

In addition, the heat-resistant resin preferably has a mass loss rate at 300° C. of not greater than 10%, more preferably not greater than 5%, and even more preferably not greater than 1%, as measured through thermogravimetry (TG). If the mass loss rate is within the range described above, even if the thin film made from the thermoelectric semiconductor composition is annealed, flexibility of the chip of the thermoelectric conversion material can be maintained without loss of function as a binder.

The content of the heat-resistant resin in the thermoelectric semiconductor composition is from 0.1 to 40 mass %, preferably from 0.5 to 20 mass %, more preferably from 1 to 20 mass %, and even more preferably from 2 to 15 mass %. When the content of the heat-resistant resin is within the range described above, the heat-resistant resin functions as a binder of the thermoelectric semiconductor material and facilitates the formation of a thin film, a film having both high thermoelectric performance and film strength is obtained, and a resin portion is present on an outer surface of the chip of the thermoelectric conversion material.

The binder resin also facilitates peeling from a base material of glass, alumina, silicon, or the like after a firing (annealing) treatment (corresponding to the “annealing treatment B” described below, same hereinafter), the base material being used when fabricating a chip of a thermoelectric conversion material.

The binder resin is preferably a resin for which 90 mass % or more decomposes at the firing (annealing) temperature or higher, is more preferably a resin for which 95 mass % or more decomposes at the firing temperature or higher, and is particularly preferably a resin for which 99 mass % or more decomposes at the firing temperature or higher. In addition, the binder resin is more preferably a resin of which various physical properties such as mechanical strength and thermal conductivity are maintained without being impaired when crystal growth of the thermoelectric semiconductor particles is caused by subjecting a coating film (thin film) formed from the thermoelectric semiconductor composition to a firing (annealing) treatment or the like.

When a resin for which 90 mass % or more decomposes at the firing (annealing) temperature or higher, that is, a resin that decomposes at a lower temperature than the heat-resistant resin described above, is used as the binder resin, the binder resin decomposes through firing, and therefore the content of the binder resin serving as an insulating component contained in the fired product is reduced, and crystal growth of the thermoelectric semiconductor particles in the thermoelectric semiconductor composition is promoted. Thus, voids in the thermoelectric conversion material layer can be reduced, and the filling ratio can be improved.

Note that whether a resin decomposes at or above a predetermined amount (for example, 90 mass %) at or above the firing (annealing) temperature is determined by measuring the mass loss rate (a value obtained by dividing the mass after decomposition by the mass before decomposition) at the firing (annealing) temperature through thermogravimetry (TG).

A thermoplastic resin or a curable resin can be used as the binder resin. Examples of thermoplastic resins include polyolefin resins such as polyethylene, polypropylene, polyisobutylene, and polymethylpentene; polycarbonates; thermoplastic polyester resins such as polyethylene terephthalate and polyethylene naphthalate; polyvinyl polymers such as polystyrene, acrylonitrile-styrene copolymers, poly(vinylacetate), ethylene-vinyl acetate copolymers, vinyl chloride, poly(vinyl pyridine), poly(vinyl alcohol), and poly(vinyl pyrrolidone); polyurethanes; and cellulose derivatives such as ethyl cellulose. Examples of the curable resins include thermosetting resins and photocurable resins. Examples of thermosetting resins include epoxy resins and phenol resins. Examples of photocurable resins include photocurable acrylic resins, photocurable urethane resins, and photocurable epoxy resins. One type of these may be used alone, or two or more types may be used in combination.

Among these, from the perspective of electrical resistivity of the thermoelectric conversion material in the thermoelectric conversion material layer, a thermoplastic resin is preferable, a polycarbonate or a cellulose derivative such as ethyl cellulose is more preferable, and a polycarbonate is particularly preferable.

The binder resin is appropriately selected according to the temperature of the firing (annealing) treatment of the thermoelectric semiconductor material in the firing (annealing) treatment process. From the perspective of electrical resistivity of the thermoelectric conversion material in the thermoelectric conversion material layer, the firing (annealing) treatment is preferably implemented at a temperature equal to or higher than the final decomposition temperature of the binder resin.

In the present specification, the “final decomposition temperature” refers to a temperature at which the mass loss rate at the firing (annealing) temperature as determined through thermogravimetry (TG) is 100% (mass after decomposition is 0% of the mass before decomposition).

The final decomposition temperature of the binder resin is typically from 150 to 600° C., preferably from 200 to 560° C., more preferably from 220 to 460° C., and particularly preferably from 240 to 360° C. When a binder resin having a final decomposition temperature within this range is used, the binder resin functions as a binder for the thermoelectric semiconductor material, and formation of a thin film is facilitated when printing.

The content of the binder resin in the thermoelectric semiconductor composition is from 0.1 to 40 mass %, preferably from 0.5 to 20 mass %, more preferably from 0.5 to 10 mass %, and particularly preferably from 0.5 to 5 mass %. When the content of the binder resin is within the range described above, the electrical resistivity of the thermoelectric conversion material in the thermoelectric conversion material layer can be reduced.

The content of the binder resin in the thermoelectric conversion material is preferably from 0 to 10 mass %, more preferably from 0 to 5 mass %, and particularly preferably from 0 to 1 mass %. In a case where the content of the binder resin in the thermoelectric conversion material is within the range described above, the electrical resistivity of the thermoelectric conversion material in the thermoelectric conversion material layer can be reduced.

(Ionic liquid)

The ionic liquid that can be included in the thermoelectric semiconductor composition is a molten salt formed by combining a cation and an anion, and refers to a salt that can be present in a liquid in a temperature range from −50° C. to lower than 400° C. In other words, the ionic liquid is an ionic compound having a melting point in a range from −50° C. to lower than 400° C. The melting point of the ionic liquid is preferably from −25° C. to 200° C., and more preferably from 0° C. to 150° C. The ionic liquid exhibits characteristics such as being nonvolatile with an extremely low vapor pressure, having excellent thermal stability and electrochemical stability, having low viscosity, and having high ionic conductivity, and therefore, as an electrical conduction auxiliary agent, the ionic liquid can effectively suppress a reduction in electrical conductivity between the thermoelectric semiconductor materials. Furthermore, the ionic liquid exhibits a high polarity based on an aprotic ion structure and excels in miscibility with the heat-resistant resin, and therefore the ionic liquid can facilitate uniformity in the electrical conductivity of the thermoelectric conversion material.

A well-known or commercially available ionic liquid can be used as the ionic liquid. Examples include ionic liquids constituted from a cationic component such as a nitrogen-containing cyclic cationic compound or derivative thereof, such as pyridinium, pyrimidinium, pyrazolium, pyrrolidinium, piperidinium, and imidazolium; a tetraalkylammonium-based amine cation or derivative thereof; a phosphinic cation or derivative thereof, such as phosphonium, trialkyl sulfonium, and tetraalkyl phosphonium; or a lithium cation or derivative thereof; and an anionic component such as Cl⁻, Br⁻, I⁻, AlCl₄⁻, Al₂Cl₇⁻, BF₄⁻, PF₆⁻, ClO₄⁻, NO₃, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, or (CF₃SO₂)(CF₃CO)N⁻.

Among the ionic liquids described above, from perspectives such as high temperature stability, miscibility between the thermoelectric semiconductor material and the resin, and suppressing a reduction in electrical conductivity of gaps in the thermoelectric semiconductor material, the cationic component of the ionic liquid preferably contains at least one selected from pyridinium cations and derivatives thereof and imidazolium cations and derivatives thereof.

Specific examples of ionic liquids in which the cationic component includes pyridinium cations or derivative thereof include 4-methyl-butylpyridinium chloride, 3-methyl-butylpyridinium chloride, 4-methyl-hexylpyridinium chloride, 3-methyl-hexylpyridinium chloride, 4-methyl-octylpyridinium chloride, 3-methyl-octylpyridinium chloride, 3,4-dimethyl-butylpyridinium chloride, 3,5-dimethyl-butylpyridinium chloride, 4-methyl-butylpyridinium tetrafluoroborate, 4-methyl-butylpyridinium hexafluorophosphate, 1-butylpyridinium bromide, 1-butyl-4-methylpyridinium bromide, and 1-butyl-4-methylpyridinium hexafluorophosphate. Among these, 1-butyl-4-methylpyridinium bromide, 1-butylpyridinium bromide, and 1-butyl-4-methylpyridinium hexafluorophosphate are preferred.

Also, specific examples of ionic liquids in which the cationic component includes imidazolium cations or derivative thereof include [1-butyl-3-(2-hydroxyethyl)imidazolium bromide], [1-butyl-3-(2-hydroxyethyl)imidazolium tetrafluoroborate], 1-ethyl-3-methylimidazolium chloride, 1-ethyl-3-methylimidazolium bromide, 1-butyl-3-methylimidazolium chloride, 1-hexyl-3-methylimidazolium chloride, 1-octyl-3-methylimidazolium chloride, 1-decyl-3-methylimidazolium chloride, 1-decyl-3-methylimidazolium bromide, 1-dodecyl-3-methylimidazolium chloride, 1-tetradecyl-3-methylimidazolium chloride, 1-ethyl-3-methylimidazolium tetrafluoroborate, 1-butyl-3-methylimidazolium tetrafluoroborate, 1-hexyl-3-methylimidazolium tetrafluoroborate, 1-ethyl-3-methylimidazolium hexafluorophosphate, 1-butyl-3-methylimidazolium hexafluorophosphate, 1-methyl-3-butylimidazolium methylphosphate, and 1,3-dibutylimidazolium methylsulfate. Of these, [1-butyl-3-(2-hydroxyethyl)imidazolium bromide] and [1-butyl-3-(2-hydroxyethyl)imidazolium tetrafluoroborate] are preferable.

The ionic liquid described above preferably has an electrical conductivity of 10⁻⁷ S/cm or higher. If the electrical conductivity is within the range described above, as an electrical conduction auxiliary agent, the ionic liquid can effectively suppress a reduction in electrical conductivity between the thermoelectric semiconductor materials.

Furthermore, the decomposition temperature of the ionic liquid is preferably 300° C. or higher. If the decomposition temperature is within the range described above, the effect as an electrical conduction auxiliary agent can be maintained even in a case in which the thin film formed from the thermoelectric semiconductor composition is annealed as described below.

In addition, the ionic liquid preferably has a mass loss rate at 300° C. of not greater than 10%, more preferably not greater than 5%, and even more preferably not greater than 1%, as measured through thermogravimetry (TG). If the mass loss rate is within the range described above, the effect as an electrical conduction auxiliary agent can be maintained even in a case in which a thin film formed from the thermoelectric semiconductor composition is annealed as described below.

The compounded amount of the ionic liquid in the thermoelectric semiconductor composition is preferably from 0.01 to 50 mass %, more preferably from 0.5 to 30 mass %, and even more preferably from 1.0 to 20 mass %. If the compounded amount of the ionic liquid is within the range described above, a reduction in electrical conductivity can be effectively suppressed, and a film having high thermoelectric performance can be obtained.

### (Inorganic Ionic Compound)

The inorganic ionic compound used in the present invention is a compound constituted from at least a cation and an anion. The inorganic ionic compound is a solid at room temperature, has a melting point at any temperature in a temperature range of from 400 to 900° C., and exhibits high ionic conductivity, and therefore as an electrical conduction auxiliary agent, the inorganic ionic compound can suppress a reduction in electrical conductivity between the thermoelectric semiconductor particles.

A metal cation is used as the cation.

Examples of the metal cation include alkali metal cations, alkaline earth metal cations, typical metal cations, and transition metal cations, and alkali metal cations or alkaline earth metal cations are more preferable.

Examples of the alkali metal cations include Li⁺, Na⁺, K⁺, Rb⁺, Cs⁺, and Fr⁺.

Examples of the alkaline earth metal cation include Mg²⁺, Ca²⁺, Sr²⁺, and Ba²⁺.

Examples of the anions include F⁻, Cl⁻, Br⁻, I⁻, OH⁻, CN⁻, NO₃⁻, NO₂⁻, ClO⁻, ClO₂⁻, ClO₃⁻, ClO₄⁻, CrO₄²⁻, HSO₄⁻, SCN⁻, BF₄⁻, and PF₆⁻.

Well-known or commercially available inorganic ionic compounds can be used. Examples of inorganic ionic compounds include those constituted from a cationic component such as a potassium cation, a sodium cation, or a lithium cation, and an anionic component such as a chloride ion such as Cl⁻, AlCl₄⁻, Al₂Cl₇⁻, or ClO₄⁻; a bromide ion such as Br⁻; an iodide ion such as I⁻; a fluoride ion such as BF₄⁻ or PF₆⁻; a halide anion such as F(HF)ₙ⁻; NO₃⁻; OH⁻; or CN⁻.

Among the inorganic ionic compounds described above, from the perspective of high temperature stability, miscibility between the thermoelectric semiconductor particles and the resin, and suppressing a reduction in electrical conductivity of the gaps between the thermoelectric semiconductor particles, the cationic component of the inorganic ionic compound preferably contains at least one selected from potassium, sodium, and lithium. Furthermore, the anionic component of the inorganic ionic compound preferably includes a halide anion, and more preferably includes at least one selected from Cl⁻, Br⁻, and I⁻.

Specific examples of the inorganic ionic compound containing a potassium cation as the cationic component include KBr, KI, KCl, KF, KOH, and K₂CO₃. Of these, KBr and KI are preferable.

Specific examples of the inorganic ionic compound containing a sodium cation as the cationic component include NaBr, NaI, NaOH, NaF, and Na₂CO₃. Of these, NaBr and NaI are preferable.

Specific examples of the inorganic ionic compound containing a lithium cation as the cationic component include LiF, LiOH, and LiNO₃. Of these, LiF and LiOH are preferable.

The inorganic ionic compound described above preferably has an electrical conductivity of 10⁻⁷ S/cm or greater and more preferably 10⁻⁶ S/cm or greater. In a case where the electrical conductivity is within the range described above, as an electrical conduction auxiliary agent, the inorganic ionic compound can effectively suppress a reduction in electrical conductivity between the thermoelectric semiconductor particles.

Furthermore, the decomposition temperature of the inorganic ionic compound described above is preferably 400° C. or higher. In a case where the decomposition temperature is within the range described above, the effect as an electrical conduction auxiliary agent can be maintained even in a case in which the thin film formed from the thermoelectric semiconductor composition is annealed as described below.

In addition, the inorganic ionic compound preferably has a mass loss rate at 400° C. of not greater than 10%, more preferably not greater than 5%, and even more preferably not greater than 1%, as measured through thermogravimetry (TG). In a case where the mass loss rate is within the range described above, the effect as an electrical conduction auxiliary agent can be maintained even in a case in which a thin film formed from the thermoelectric semiconductor composition is annealed as described below.

The compounded amount of the inorganic ionic compound in the thermoelectric semiconductor composition is preferably from 0.01 to 50 mass %, more preferably from 0.5 to 30 mass %, and even more preferably from 1.0 to 10 mass %. In a case where the compounded amount of the inorganic ionic compound is within the range described above, a reduction in electrical conductivity can be effectively suppressed, and as a result, a film with improved thermoelectric performance can be obtained.

Note that when the inorganic ionic compound and the ionic liquid are used in combination, the total amount of the inorganic ionic compound and the ionic liquid in the thermoelectric semiconductor composition is preferably from 0.01 to 50 mass %, more preferably from 0.5 to 30 mass %, and even more preferably from 1.0 to 10 mass %.

### (Method for Preparing Thermoelectric Semiconductor Composition)

The method for preparing the thermoelectric semiconductor composition used in the present invention is not particularly limited, and the thermoelectric semiconductor composition can be prepared by, for example, adding the thermoelectric semiconductor particles, the ionic liquid, the inorganic ionic compound (when used in combination with the ionic liquid), the heat-resistant resin, and as necessary, the other additives and also a solvent, and mixing and dispersing the various components through a well-known method such as an ultrasonic homogenizer, a spiral mixer, a planetary mixer, a disperser, or a hybrid mixer.

Examples of the solvent include solvents such as toluene, ethyl acetate, methyl ethyl ketone, alcohol, tetrahydrofuran, methyl pyrrolidone, and ethyl cellosolve. One type of these solvents may be used alone, or two or more may be mixed and used in combination. The solid content concentration of the thermoelectric semiconductor composition is not particularly limited as long as the composition has a viscosity suitable for coating.

The chip of the thermoelectric conversion material formed from the thermoelectric semiconductor composition is not particularly limited, and, for example, can be formed by obtaining a coating by coating the thermoelectric semiconductor composition onto a base material such as glass, alumina, or silicon, or onto a base material on a side on which a below-described sacrificial layer is formed, and then drying the coating. By forming in this manner, numerous chips of the thermoelectric conversion material can be easily obtained at a low cost.

The method for coating the thermoelectric semiconductor composition onto a base material to obtain a chip of a thermoelectric conversion material is not particularly limited, and examples include well-known methods such as screen printing, flexographic printing, gravure printing, spin coating, dip coating, die coating, spray coating, bar coating, and doctor blade coating. When the coating is to be formed in a pattern, a method such as screen printing or slot die coating by which the pattern can be easily formed using a screen plate having the desired pattern is preferably used.

Next, the obtained coating is dried, and thereby a chip of the thermoelectric conversion material is formed. As the drying method, a well-known drying method can be used, such as hot air drying, heated roll drying, and infrared irradiation. The heating temperature is typically from 80 to 150° C., and while the heating time differs depending on the heating method, the heating time is typically from tens of seconds to tens of minutes.

Furthermore, when a solvent is used in the preparation of the thermoelectric semiconductor composition, the heating temperature is not particularly limited as long as the temperature is within a temperature range in which the solvent that is used can be dried.

The thickness of the thin film formed from the thermoelectric semiconductor composition is not particularly limited, but from the perspective of thermoelectric performance and film strength, the thickness of the thin film is preferably from 100 nm to 1000 μm, more preferably from 300 nm to 600 μm, and even more preferably from 5 to 400 μm.

As a thin film made from the thermoelectric semiconductor composition, the chip of the thermoelectric conversion material is preferably further subjected to an annealing treatment (corresponding to the firing (annealing) described above and referred to hereinafter as the “annealing treatment B”). By subjecting the chip to the annealing treatment B, the thermoelectric performance can be stabilized, crystal growth of the thermoelectric semiconductor particles in the thin film can be promoted, and the thermoelectric performance can be further improved. The annealing treatment B is not particularly limited, but is ordinarily implemented in an atmosphere with the gas flow rate controlled, including in an inert gas atmosphere such as nitrogen or argon or in a reducing gas atmosphere, or is implemented under vacuum conditions, and while dependent on factors such as the heat resistance temperatures of the resin and ionic compound that are used, the annealing treatment B is typically implemented at a temperature of from 100 to 500° C. for several minutes to several tens of hours.

As the sacrificial layer, a resin such as poly(methyl methacrylate) or polystyrene, or a release agent such as a fluorine-based release agent or a silicone-based release agent can be used. When a sacrificial layer is used, the chip of the thermoelectric conversion material formed on a base material such as glass can easily be peeled from the glass or the like after the annealing treatment B.

The formation of the sacrificial layer is not particularly limited, and the sacrificial layer can be formed by a well-known method such as flexographic printing or spin coating.

### <Substrate>

The substrates of the thermoelectric conversion module used in the present invention, that is, the first substrate and the second substrate, are not particularly limited, and each substrate can independently be a known substrate such as a glass substrate, a silicon substrate, a ceramic substrate, or a resin substrate.

A plastic film (resin substrate) that does not affect flexibility or a decrease in electrical conductivity and an increase in thermal conductivity of the chip of the thermoelectric conversion material is preferably used. Of these, from the perspectives of excelling in flexibility, being able to maintain performance of the thermoelectric conversion module without thermal deformation of the substrate even when the thin film formed from the thermoelectric semiconductor composition is annealed, and having high levels of heat resistance and dimensional stability, the plastic film is preferably a polyimide film, a polyamide film, a polyetherimide film, a polyaramid film, or a polyamide-imide film, and from the perspective of high versatility, a polyimide film is particularly preferable.

From the perspectives of flexibility, heat resistance, and dimensional stability, the plastic films used in the first substrate and the second substrate independently have a thickness of preferably from 1 to 1000 μm, more preferably from 10 to 500 μm, and even more preferably from 20 to 100 μm.

In addition, the 5% weight loss temperature measured by thermogravimetry is preferably 300° C. or higher, and more preferably 400° C. or higher. The dimensional change rate due to heat as measured at 200° C. in accordance with JIS K7133 (1999) is preferably 0.5% or less, and more preferably 0.3% or less. The linear expansion coefficient in the planar direction as measured in accordance with JIS K7197 (2012) is from 0.1 ppm·° C.⁻¹ to 50 ppm·° C.⁻¹, and is more preferably from 0.1 ppm·° C.⁻¹ to 30 ppm·° C.⁻¹.

### <Electrode>

Examples of the respective metal materials of the first electrode and the second electrode of the thermoelectric conversion module used in the present invention include gold, nickel, aluminum, rhodium, platinum, chromium, palladium, stainless steel, molybdenum, or alloys containing any of these metals.

The thicknesses of the respective layers of the first electrode and the second electrode are preferably from 10 nm to 200 μm, more preferably from 30 nm to 150 μm, and even more preferably from 50 nm to 120 μm. If the thicknesses of the respective layers of the electrodes are within the range described above, electrical conductivity is high, resistance is low, and sufficient strength of an electrode is obtained.

The first electrode and the second electrode are formed using the metal material.

Examples of methods for forming the electrodes include a method of processing the substrate into a predetermined pattern shape by a known physical treatment or chemical treatment based on photolithography or by using these treatments in combination, and a method of directly forming the pattern of the electrode layer through screen printing, stencil printing, inkjet printing, or the like.

Examples of methods for forming an electrode on which a pattern is not formed include vacuum film formation methods such as physical vapor deposition (PVD) methods, such as vacuum vapor deposition, sputtering, and ion plating, or chemical vapor deposition (CVD) methods, such as thermal CVD and atomic layer deposition (ALD), or a wet process such as various coating methods including dip coating, spin coating, spray coating, gravure coating, die coating, or doctor blade coating, and electrodeposition methods, as well as a silver salt method, electrolytic plating, electroless plating, and lamination of metal foils. The method thereof is appropriately selected according to the material of the substrate.

In the present invention, from the perspective of maintaining thermoelectric performance, the electrodes are required to exhibit high electrical conductivity and high thermal conductivity, and therefore use of an electrode that has been film formed by screen printing, stencil printing, electrolytic plating, electroless plating, or a vacuum film formation method is preferable. A pattern can be easily formed through a hard mask such as a metal mask depending on the dimensions of the pattern to be formed and the required dimensional accuracy. Furthermore, when the film is formed by a vacuum film formation method, in order to improve adhesion with the substrate that is used and remove moisture, the film may be formed while heating the substrate that is used as long as heating does not impair the characteristics of the substrate. In the case of film formation using a plating method, the film may be formed by electrolytic plating on a film that has been formed by electroless plating.

As is clear from the first embodiment and the second embodiment, the thermoelectric conversion module of the present invention is configured such that the melting point of the second bonding material constituting the thermoelectric conversion module is lower than the melting point of the first bonding material, or the melting point of the second bonding material is lower than the curing temperature of the first bonding material. Therefore, positional deviation of the chip of the thermoelectric conversion material on the electrode, the positional deviation occurring due to the first bonding material when bonding the second bonding material, can be prevented, and short circuiting between adjacent chips of thermoelectric conversion materials and bonding defects between an electrode and a chip of the thermoelectric conversion material are suppressed, and as a result, an improvement in thermoelectric performance can be achieved.

### [Method for Manufacturing the Thermoelectric Conversion Module]

The present invention provides a method for manufacturing the thermoelectric conversion module that includes: a first substrate having a first electrode; a second substrate having a second electrode; a chip of a thermoelectric conversion material made from a thermoelectric semiconductor composition; a first bonding material layer made from a first bonding material and bonding one surface of the chip of the thermoelectric conversion material and the first electrode; and a second bonding material layer made from a second bonding material and bonding another surface of the chip of the thermoelectric conversion material and the second electrode, and the manufacturing method includes:
(a) a step of forming, on the first electrode on the first substrate, the first bonding material layer made from the first bonding material;
(b) a step of mounting one surface of the chip of the thermoelectric conversion material on the first bonding material layer obtained in step (a);
(c) a first bonding step of bonding, to the first electrode, one surface of the chip of the thermoelectric conversion material mounted in step (b), by interposing and heating the first bonding material layer obtained in step (a);
(d) a step of forming, on the second electrode on the second substrate, the second bonding material layer made from the second bonding material;
(e) a step of pasting together the other surface of the chip of the thermoelectric conversion material on the first substrate and the second bonding material layer obtained in step (d); and
(f) a second bonding step of bonding the other surface of the chip of the thermoelectric conversion material after the step (e) to the second electrode by interposing and heating the second bonding material layer; and
the manufacturing method is characterized in that a bonding temperature of the second bonding step is lower than a bonding temperature of the first bonding step.

Hereinafter, step (a) may be referred to as the “first bonding material layer formation step”, step (b) may be referred to as the “thermoelectric conversion material chip mounting step”, step (c) may be referred to as the “first bonding step”, step (d) may be referred to as the “second bonding material layer formation step”, step (e) may be referred to as the “second bonding material layer pasting step”, and step (f) may be referred to as the “second bonding step”.

The steps included in the present invention will be described sequentially.

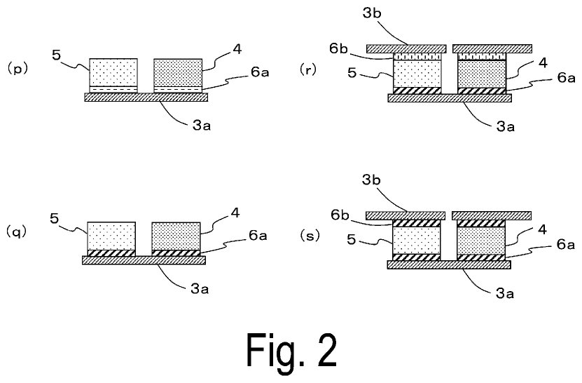

FIG. 2 is an explanatory diagram illustrating, in order of the steps, an example of a method for bonding a chip of a thermoelectric conversion material and an electrode in the method for manufacturing a thermoelectric conversion module of the present invention. FIG. 2(p) is a cross-sectional view after a first bonding material layer 6a formed from a first bonding material has been formed on a first electrode 3a on a first substrate 2a (not illustrated), and one surface of each of a chip 4 of a P-type thermoelectric conversion material and a chip 5 of an N-type thermoelectric conversion material has been mounted thereon. FIG. 2(q) is a cross-sectional view illustrating an aspect in which after the step of (p), the bonding material layer 6a is cured by heating, and the one surface of the chip 4 of the P-type thermoelectric conversion material and the one surface of the chip 5 of the N-type thermoelectric conversion material are bonded to the first electrode 3a. FIG. 2(r) is a cross-sectional view after a second bonding material layer 6b formed from a second bonding material has been formed on a second electrode 3b on a second substrate 2b (not illustrated), and then pasted together with the other surface of each of the chip 4 of the P-type thermoelectric conversion material and the chip 5 of the N-type thermoelectric conversion material. FIG. 2(s) is a cross-sectional view illustrating an aspect in which after the step of (r), the bonding material layer 6b is cured by heating, and the other surface of the chip 4 of the P-type thermoelectric conversion material and the other surface of the chip 5 of the N-type thermoelectric conversion material are bonded to the second electrode 3b.

### <First Bonding Material Layer Formation Step>

The first bonding material layer formation step is the step (a) of the method for manufacturing the thermoelectric conversion module of the present invention, and is a step of forming the first bonding material layer on the first electrode using the first bonding material.

The first bonding material layer is used to bond one surface of each of the chip of the P-type thermoelectric conversion material and the chip of the N-type thermoelectric conversion material to the first electrode. In the present invention, for example, the aforementioned solder material or conductive adhesive material is used as the first bonding material.

The thickness of the first bonding material layer, the method of coating onto the first electrode, and the like are as described above.

### <Thermoelectric Conversion Material Chip Mounting Step>

The thermoelectric conversion material chip mounting step is the step of (b) of the method for manufacturing a thermoelectric conversion module of the present invention, and is a step of mounting one surface of a chip of the thermoelectric conversion material on the first bonding material layer obtained in step (a). For example, step (b) is a step of mounting one surface of a chip of a P-type thermoelectric conversion material and one surface of a chip of an N-type thermoelectric conversion material on an upper surface of a corresponding first bonding material layer using a hand unit such as a chip mounter.

In the present invention, with regard to the arrangement of the chip of the P-type thermoelectric conversion material and the chip of the N-type thermoelectric conversion material, from the perspective of obtaining theoretically high thermoelectric performance, a plurality of pairs of the chip of the P-type thermoelectric conversion material and the chip of the N-type thermoelectric conversion material are preferably disposed with electrodes interposed.

The method of mounting the chips of the thermoelectric conversion materials onto the bonding material layer is not particularly limited, and a known method is used. Examples thereof include a method in which one or a plurality of chips of a thermoelectric conversion material are handled by a chip mounter or the like described above, aligned using a camera or the like, and mounted.

From the perspectives of handling ease, mounting precision, and mass producibility, the chip of the thermoelectric conversion material is preferably mounted using a chip mounter.

### <First Bonding Step>

The first bonding step is the step (c) of the method for manufacturing a thermoelectric conversion module of the present invention, and is a step in which one surface of the chip of thermoelectric conversion material mounted in step (b) is bonded to the first electrode by interposing and heating the first bonding material layer obtained in step (a), and for example, is a step in which the first bonding material layer is heated to a predetermined temperature and maintained at that temperature for a predetermined period of time, and then returned to room temperature.

The bonding conditions such as the heating temperature (bonding temperature) and temperature retention time are as described above.

### <Second Bonding Material Layer Formation Step>

The second bonding material layer formation step is the step (d) of the method for manufacturing the thermoelectric conversion module of the present invention, and is a step of forming the second bonding material layer on the second electrode using the second bonding material.

The second bonding material layer is used to bond the other surface of each of the chip of the P-type thermoelectric conversion material and the chip of the N-type thermoelectric conversion material to the second electrode.

In the present invention, for example, the solder material described above is used as the second bonding material.

The thickness of the second bonding material layer, the method of coating onto the second electrode, and the like are as described above.

### <Second Bonding Material Layer Pasting Step>

The second bonding material layer pasting step is the step (e) of the method for manufacturing the thermoelectric conversion module of the present invention, and is a step of pasting together the other surface of the chip of the thermoelectric conversion material on the first substrate and the second bonding material layer obtained in step (d).

Examples of methods for pasting together the second bonding material layer and the other surface of the chip of the thermoelectric conversion material include known methods such as lamination.

### <Second Bonding Step>

The second bonding step is the step (f) of the method for manufacturing the thermoelectric conversion module of the present invention, and is a step of bonding the other surface of the chip of the thermoelectric conversion material to the second electrode by interposing and heating the second bonding material layer obtained in step (d). For example, the second bonding step is a step in which the second bonding material layer is heated to a predetermined temperature and maintained at that temperature for a predetermined period of time, and then returned to room temperature.

The bonding conditions such as the heating temperature (bonding temperature) and temperature retention time are as described above.

The heating method in the first bonding step and the second bonding step is not particularly limited, and examples include a method in which some or all of the connection structure is heated using a reflow furnace or an oven, or a method of heating only the connecting portion of the connection structure in a localized manner.

In the case of heating by reflow, for example, a connection structure having the first electrode, the first bonding material layer and the chip of the thermoelectric conversion material all laminated on the first substrate, and the entirety of a connection structure including the second bonding material layer obtained in the pasting step are arranged inside a reflow furnace and heated.

Additionally, examples of devices used in the method of localized heating include hot plates, heat guns that apply hot air, soldering irons, and infrared heaters.

In the first bonding step and the second bonding step of the present invention, a continuous heating treatment through reflow is preferable from the perspectives of heating the connection structures, manufacturing ease, and shortening of the tact time.

Heating by reflow differs depending on the combination of the first bonding material and the second bonding material, but can be implemented at the heating conditions, etc. pertaining to the aforementioned solder material and conductive adhesive material.

Another example of a method for manufacturing the thermoelectric conversion module is a manufacturing method that includes the following manufacturing steps (i) to (x):
(i) a step of forming, on a first electrode on a first substrate, a first bonding material layer made from a first bonding material;
(ii) a step of mounting one surface of a chip of a P-type thermoelectric conversion material onto the first bonding material layer obtained in step (i);
(iii) a first bonding step of bonding, to the first electrode, one surface of the chip of the P-type thermoelectric conversion material mounted in step (ii), by interposing and heating the first bonding material layer obtained in step (i);
(iv) a step of forming, on the other surface of the chip of the P-type thermoelectric conversion material after step (iii), a second bonding material layer made from a second bonding material;
(v) a step of forming, on a second electrode on a second substrate, a first bonding material layer made from a first bonding material;
(vi) a step of mounting one surface of a chip of an N-type thermoelectric conversion material onto the first bonding material layer obtained in step (v);
(vii) a third bonding step of bonding, to the second electrode, one surface of the chip of the N-type thermoelectric conversion material mounted in step (vi), by interposing and heating the first bonding material layer obtained in step (v);
(viii) a step of forming, on the other surface of the chip of the N-type thermoelectric conversion material after step (vii), a second bonding material layer made from a second bonding material;
(ix) a step of pasting together the second bonding material layer obtained in step (viii) and the first electrode of the first substrate after step (iv), and pasting together the second bonding material layer obtained in step (iv) and the second electrode of the second substrate after step (viii); and
(x) a fourth bonding step of bonding the other surface of the chip of the N-type thermoelectric conversion material after step (viii) to the first electrode of the first substrate after step (iv) by interposing and heating the second bonding material layer obtained in step (viii), and a fifth bonding step of bonding the other surface of the chip of the P-type thermoelectric conversion material after step (iv) to the second electrode of the second substrate after step (viii) by interposing and heating the second bonding material layer obtained in step (iv), wherein
the bonding temperature of the fourth bonding step and the bonding temperature of the fifth bonding step are lower than the bonding temperature of the first bonding step and the bonding temperature of the third bonding step.

Note that in the third bonding step, bonding is implemented under the same conditions as the heating temperature (bonding temperature), temperature retention time, and the like described with regard to the aforementioned first bonding step, and in the fourth bonding step and the fifth bonding step, bonding is simultaneously implemented under the same conditions as the heating temperature (bonding temperature), temperature retention time, and the like described with regard to the aforementioned second bonding step.

With this method, for example, first, a substrate obtained by bonding one surface of a chip of a P-type thermoelectric conversion material to a first electrode on a first substrate by interposing a first bonding material layer, and then forming a second bonding material layer on the other surface of the chip of the P-type thermoelectric conversion material (only the chip of the P-type thermoelectric conversion material is present on the first substrate), and a substrate obtained by bonding one surface of a chip of an N-type thermoelectric conversion material to a second electrode of a second substrate by interposing a first bonding material layer, and then forming a second bonding material layer on the other surface of the chip of the N-type thermoelectric conversion material (only the chip of the N-type thermoelectric conversion material is present on the second substrate) are manufactured. Next, the surface of the obtained substrate having the chip of the P-type thermoelectric conversion material and the surface of the obtained substrate having the chip of the N-type thermoelectric conversion material are disposed facing each other, and the chip of the P-type thermoelectric conversion material and the chip of the N-type thermoelectric conversion material are pasted together so as to be electrically connected in series in an alternating manner across each electrode (π-type thermoelectric conversion element configuration), and thereby the other surface of the chip of the P-type thermoelectric conversion material is bonded to the second electrode of the second substrate with the second bonding material layer interposed, and the other surface of the chip of the N-type thermoelectric conversion material is bonded to the first electrode of the first substrate with the second bonding material layer interposed.

Of course, as stipulated by the present invention, the bonding temperature of the second bonding material layer is set lower than the bonding temperature of the first bonding material layer.

Note that with regard to the arrangement of the chip of the P-type thermoelectric conversion material on the first electrode of the first substrate and the arrangement of the chip of the N-type thermoelectric conversion material on the second electrode of the second substrate, when both substrates are pasted together, as described above, the chip of the P-type thermoelectric conversion material and the chip of the N-type thermoelectric conversion material are electrically connected in series in an alternating manner across each electrode (π-type thermoelectric conversion element configuration).

According to the method for manufacturing a thermoelectric conversion module of the present invention, positional deviation of a chip of a thermoelectric conversion material on an electrode that occurs due to a first bonding material when bonding a second bonding material can be prevented, and short circuiting between adjacent chips of thermoelectric conversion materials and bonding defects between an electrode and a chip of the thermoelectric conversion material are suppressed, and therefore manufacturing yield is improved, and tact time is reduced.

### REFERENCE SIGNS LIST

1: Thermoelectric conversion module
2a: First substrate
2b: Second substrate
3a: First electrode
3b: Second electrode
4: Chip of P-type thermoelectric conversion material
5: Chip of N-type thermoelectric conversion material
6a: First bonding material layer
6b: Second bonding material layer

1. A thermoelectric conversion module comprising: a first substrate having a first electrode; a second substrate having a second electrode; a chip of a thermoelectric conversion material made from a thermoelectric semiconductor composition; a first bonding material layer made from a first bonding material and bonding one surface of the chip of the thermoelectric conversion material and the first electrode; and a second bonding material layer made from a second bonding material and bonding another surface of the chip of the thermoelectric conversion material and the second electrode, wherein
a melting point of the second bonding material is lower than a melting point of the first bonding material, or the melting point of the second bonding material is lower than a curing temperature of the first bonding material.

2. The thermoelectric conversion module according to claim 1, wherein a difference between the melting point of the first bonding material and the melting point of the second bonding material is 20° C. or higher.

3. The thermoelectric conversion module according to claim 1, wherein a difference between the curing temperature of the first bonding material and the melting point of the second bonding material is 20° C. or higher.

4. The thermoelectric conversion module according to claim 1, wherein the first bonding material and the second bonding material are solder materials.

5. The thermoelectric conversion module according to claim 1, wherein the first bonding material is a conductive adhesive material, and the second bonding material is a solder material.

6. The thermoelectric conversion module according to claim 1, wherein the thermoelectric semiconductor composition comprises a resin.

7. The thermoelectric conversion module according to claim 6, wherein the resin is a heat-resistant resin, and the thermoelectric semiconductor composition further comprises a thermoelectric semiconductor material and one or both of an ionic liquid and an inorganic ionic compound.

8. The thermoelectric conversion module according to claim 7, wherein the heat-resistant resin is a polyimide resin, a polyamide resin, a polyamide-imide resin, or an epoxy resin.

9. The thermoelectric conversion module according to claim 6, wherein the resin is a binder resin, and the thermoelectric semiconductor composition further comprises a thermoelectric semiconductor material and one or both of an ionic liquid and an inorganic ionic compound.

10. The thermoelectric conversion module according to claim 9, wherein the binder resin comprises at least one selected from polycarbonates, cellulose derivatives, and polyvinyl polymers.

11. A method for manufacturing a thermoelectric conversion module comprising: a first substrate having a first electrode; a second substrate having a second electrode; a chip of a thermoelectric conversion material made from a thermoelectric semiconductor composition; a first bonding material layer made from a first bonding material and bonding one surface of the chip of the thermoelectric conversion material and the first electrode; and a second bonding material layer made from a second bonding material and bonding another surface of the chip of the thermoelectric conversion material and the second electrode, the manufacturing method comprising:
(a) forming on the first electrode on the first substrate, the first bonding material layer made from the first bonding material;
(b) mounting one surface of the chip of the thermoelectric conversion material on the first bonding material layer obtained in step (a);
(c) bonding to the first electrode, one surface of the chip of the thermoelectric conversion material mounted in step (b), by interposing and heating the first bonding material layer obtained in (a);
(d) forming on the second electrode on the second substrate, the second bonding material layer made from the second bonding material;
(e) pasting together the other surface of the chip of the thermoelectric conversion material on the first substrate and the second bonding material layer obtained in (d); and
(f) bonding the other surface of the chip of the thermoelectric conversion material after (e) to the second electrode by interposing and heating the second bonding material layer; wherein
a bonding temperature of the bonding in (f) is lower than a bonding temperature of the bonding in (c).

12. The method for manufacturing a thermoelectric conversion module according to claim 11, wherein heating in the bonding in (c) and the bonding in (f) is implemented by reflow.
